(19) United States
(12) Patent Application Publication
(10) Pub. No.: US 2008/0150141 A1
(43) Pub. Date: Jun. 26, 2008

(54) Manufacturing method for an integrated semiconductor structure and corresponding semiconductor structure

(76) Inventors: Werner Graf, Dresden (DE); Andreas Thies, Berlin (DE); Marco Lepper, Dresden (DE); Momtchil Stavrev, Dresden (DE)

Correspondence Address: ESCHWEILER & ASSOCIATES LLC, NATIONAL CITY BANK BUILDING, CLEVELAND, OH, 44114, US

(21) Appl. No.: 11/652,255

(22) Filed: Jan. 11, 2007

(30) Foreign Application Priority Data
Dec. 21, 2006 (DE) 102006060770.8

(51) Int. Cl. H01L 23/52; H01L 21/4763

(52) U.S. Cl. 257/752; 438/631; 257/E23.141; 257/E21.495

(57) ABSTRACT

The present invention provides a manufacturing method for an integrated semiconductor structure comprising the steps of:
providing a semiconductor substrate with a main surface; forming a wiring metal layer above said main surface; forming a doped getter layer on said wiring metal layer; and forming at least one additional wiring metal layer on said doped getter layer. The present invention also provides a corresponding integrated semiconductor structure and a semiconductor memory device.

### BACKGROUND

1. Field of the Invention

The present invention relates to a manufacturing method for an integrated semiconductor structure and to a corresponding semiconductor structure.

2. Description of the Related Art

Although applicable to arbitrary integrated semiconductor structures, the following invention and the underlying problems will be explained with respect to integrated DRAM memory circuits in silicon technology. In particular, DRAM technology which is scaled down to below 100 nm generation provides big challenges.

Phospho-silicate glass (PSG) is used to getter mobile ions (Li, Na, K) and metal contaminants in semiconductor structures, because these elements which are still present in today's semiconductor structures deteriorate the electrical functions thereof.

FIG. 5 shows a schematic layout for illustrating a known manufacturing method for an integrated semiconductor structure according.

In FIG. 5 reference sign 1 denotes a semiconductor substrate having a (not shown) integrated circuitry, e.g. a DRAM-circuitry, and having a main surface OS with a non-planar topology. In this particular case, a plurality of gate lines G is arranged in parallel on the main surface OS, said gate lines G having a certain distance from each other and leaving spaces therebetween. Up to now a phospho-silicate glass layer PGL was deposited on such a semiconductor structure with non-planar topology as a getter layer and a planarizing layer.

However, as indicated with reference sign L in FIG. 5, due to the poor gap fill of PSG, in particular in low thermal budget process flows, unwanted voids L are formed in the spaces between the gate lines G. This makes it necessary to look for alternative gap fill materials, such as spin-on dielectrics with exhibit much better gap flow. However, these spin-on dielectrics, e.g. polysilacane based spin-on dielectrica, are usually not phosphorous doped or cannot easily be doped with phosphorous.

### SUMMARY

According to one aspect of the invention as claimed in claim 1, a manufacturing method for an integrated semiconductor structure comprises the steps of: providing a semiconductor substrate with a main surface; forming a wiring metal layer above said main surface; forming a doped getter layer on said wiring metal layer; and forming at least one additional wiring metal layer on said doped getter layer.

According to another aspect of the present invention as claimed in claim 23, an integrated semiconductor structure comprises: a semiconductor substrate with a main surface; wiring metal layer formed above said main surface; a doped getter layer formed on said wiring metal layer; and at least one additional wiring metal layer formed on said doped getter layer.

According to another aspect of the present invention as claimed in claim 39, a semiconductor memory device comprises:

a semiconductor substrate having a main surface including a plurality of non-planar gate stacks; a planarization layer for planarizing said gate stacks; a wiring metal layer formed in or on said planarization layer; an interlevel insulating layer formed on said wiring metal layer; a doped getter layer formed on said interlevel insulating layer; and at least one additional wiring metal layer formed on said doped getter layer.

One advantage of the proposed implementation is that any underlying layer may be chosen without paying attention to gettering effects thus e.g. avoiding planarizing deficites of gettering material layers.

Preferred embodiments are listed in the respective dependent claims.

### DESCRIPTION OF THE DRAWINGS

In the Figures:

FIG. 1a)-d) show schematic layouts for illustrating a manufacturing method for an integrated semiconductor structure according to a first embodiment of the present invention;

FIG. 2 shows a schematic layout for illustrating a manufacturing method for an integrated semiconductor structure according to a second embodiment of the present invention;

FIG. 3a)-c) show schematic layouts for illustrating a manufacturing method for an integrated semiconductor structure according to a third embodiment of the present invention;

FIG. 4 shows a schematic layout for illustrating a manufacturing method for an integrated semiconductor structure according to a fourth embodiment of the present invention; and

FIG. 5 shows a schematic layout for illustrating a known manufacturing method for an integrated semiconductor structure according.

In the Figures, identical reference signs denote equivalent or functionally equivalent components.

### DETAILED DESCRIPTION

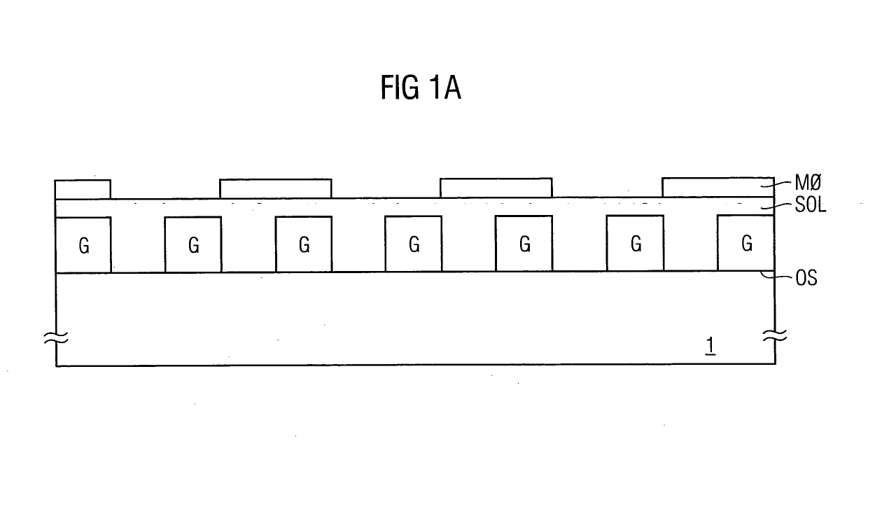

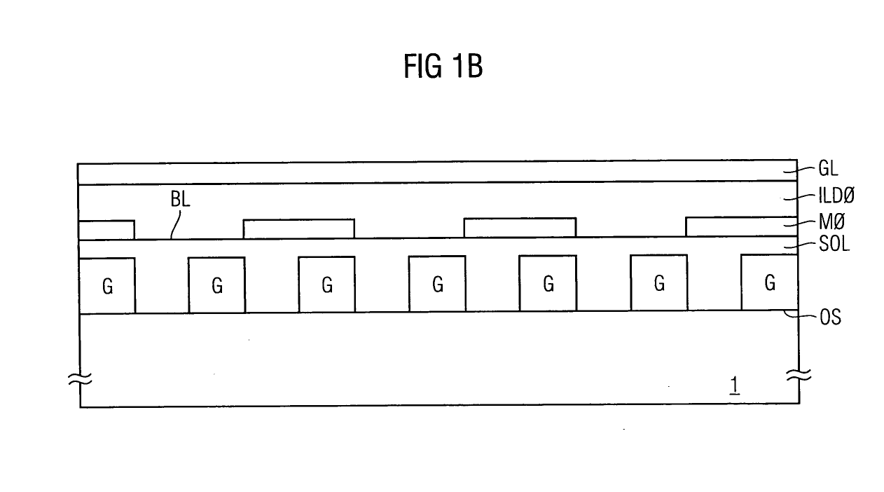

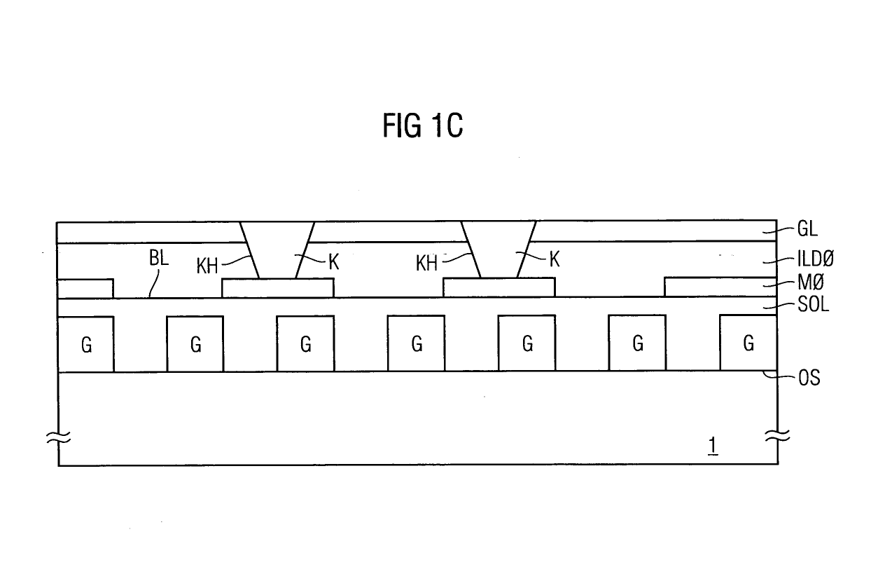

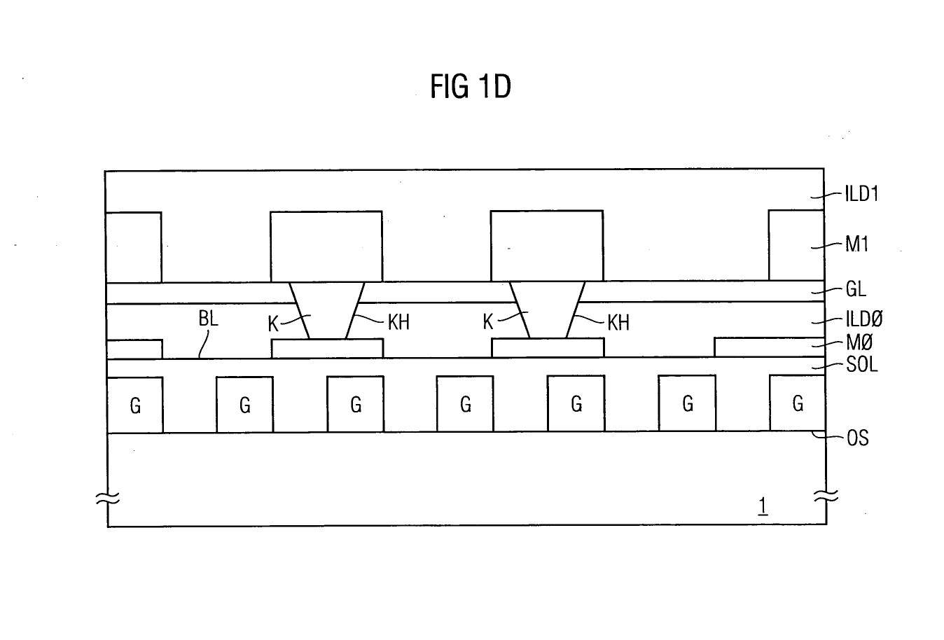

FIG. 1a)-d) show schematic layouts for illustrating a manufacturing method for an integrated semiconductor structure according to a first embodiment of the present invention.

In FIG. 1a) reference sign 1 denotes a semiconductor substrate having a (not shown) integrated circuitry, e.g. a DRAM-circuitry, and having a main surface OS with a non-planar topology. In this particular case, a plurality of gate lines G is arranged in parallel on the main surface OS, said gate lines G having a certain distance from each other and leaving spaces therebetween.

In this first embodiment, a spin-on glass layer SOL is used as a planarization and gap fill layer which exhibits excellent property regarding gap fill and essentially exhibits no unwanted voids. However, this spin-on glass layer SOL does not contain any getter material such as phosphorous.

On top of the spin-on glass layer SOL, a lowest level wiring metal layer MO is deposited and structured, e.g. a tungsten layer, by masking and etching process steps.

In a next process step which is shown in FIG. 1b) an LPCVD-oxide base layer BL is deposited on the lowest level wiring metal layer MO and the exposed parts of the spin-on glass layer SOL. Then, an interlevel insulating layer ILD0 in form of a low-K dielectric layer is deposited on the LPCVD-oxide base layer BL. The interlevel insulating layer ILD0 forms a planar surface, and after deposition of layer ILD0, a phospho-silicate glass getter layer GL is deposited over the entire structure in a gas-phase doping deposition step.

In a subsequent process step which is shown in FIG. 1c) a (not shown) hard mask, e.g. made of carbon, is formed on top of the structure of FIG. 1b), said hard mask layer having openings at the position of electrical contacts K to be formed at this process state. Then, using the hard mask, contact holes KH are etched which extend through the getter layer GL and the interlevel insulating layer ILD0 down to regions of the lowest level wiring metal layer MO to be contacted. Subsequently, tungsten is deposited over the entire structure and polished back to the upper surface of the getter layer GL in order to reach the process state shown in FIG. 1c) showing said contacts K in said contact holes KH.

Then, as shown in FIG. 1d) a second level wiring metal layer M1 made of TiN is deposited and structured by known processes. Finally, another interlevel insulating layer ILD1 is deposited over the second level wiring metal layer M1 which leads to the process state shown in FIG. 1d).

In the semiconductor structure shown in FIG. 1d), the phospho-silicate glass getter layer GL is arranged above the lowest level wiring layer M0 and has no longer any influence regarding the gap fill properties arising in connection with the non-planar topology of the underlying semiconductor structure 1, G.

Although described here as pure phospho-silicate glass layer, it is of course possible to have a mixed layer such as a boro-phospho-silicate glass layer, typically with a phosphorous content between 0.01%-10% by weight. Even though the mentioned phosphorous content may be advantageous it is only an example and other contents may be possible.

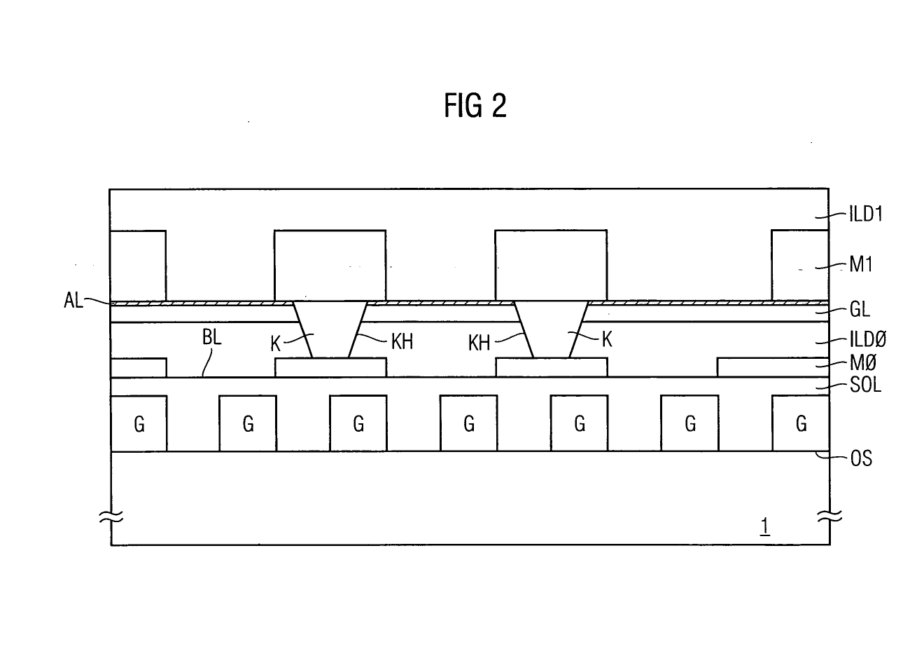

FIG. 2 shows a schematic layout for illustrating a manufacturing method for an integrated semiconductor structure according to a second embodiment of the present invention.

According to the second embodiment shown in FIG. 2, the process state of which essentially corresponds to the process state shown in FIG. 1d), an adhesive layer AL is deposited on the getter layer GL after formation thereof and before formation of the contacts K. This adhesive layer AL is for example an undoped silane-oxinitride (SiON) layer which also acts as a diffusion barrier against unwanted external ions coming from above. This is beneficial, because the getter layer GL shows the tendency to be saturated after having received a certain amount of foreign ions to be gettered.

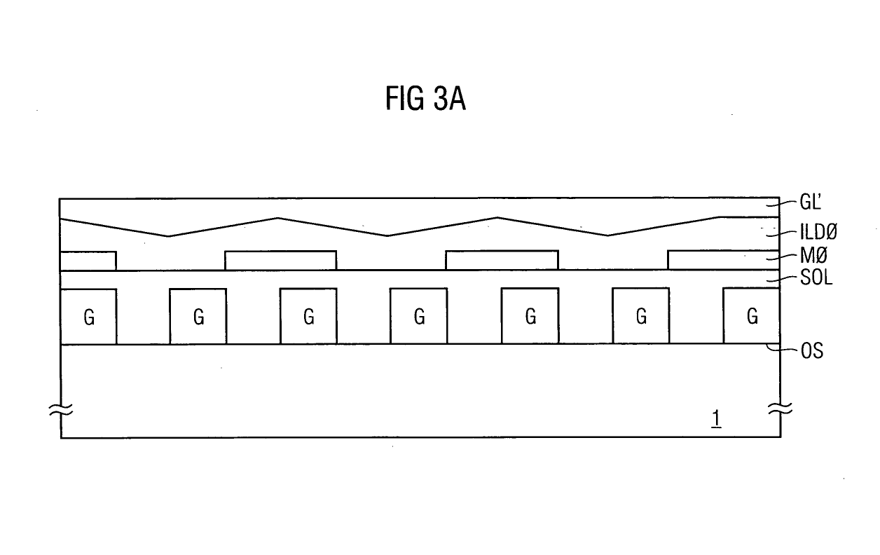

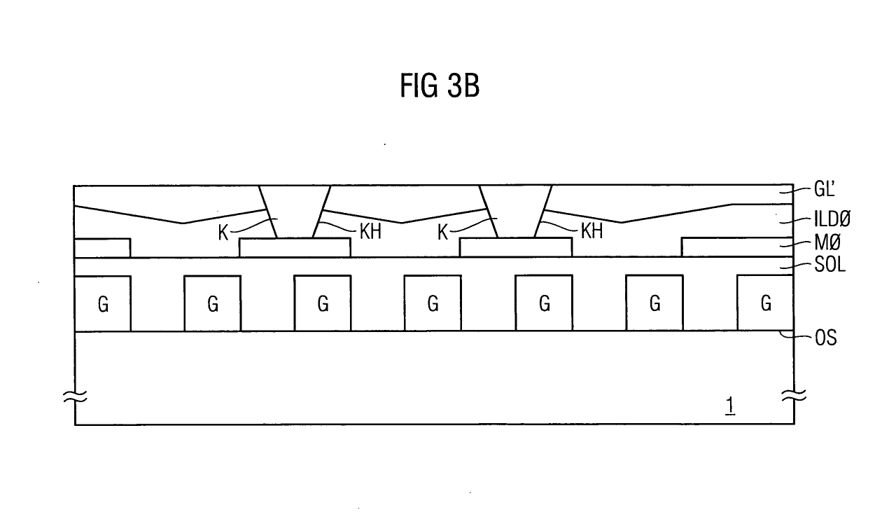

FIG. 3a)-c) show schematic layouts for illustrating a manufacturing method for an integrated semiconductor structure according to a third embodiment of the present invention.

The process state shown in FIG. 3a) corresponds to the process state shown in FIG. 1b), except for the following differences.

Namely, in this third embodiment, the interlevel insulating layer ILD0 is a high-density plasma-oxide layer which after deposition shows a non-planar surface. After deposition of this interlevel insulating layer ILD0, a getter layer GL′ made of phospho-silicate glass is deposited over the non-planar surface of the interlevel insulating layer ILD0 and thereafter polished back in chemical-mechanical polishing step, so as to reach the process state shown in FIG. 3a).

The contact K formation step shown in FIG. 3b) corresponds to the contact K formation step described in connection with FIG. 1c).

Also, the second level wiring metal layer M1 formation step shown in FIG. 3c) corresponds to the steps described already with reference to FIG. 1d).

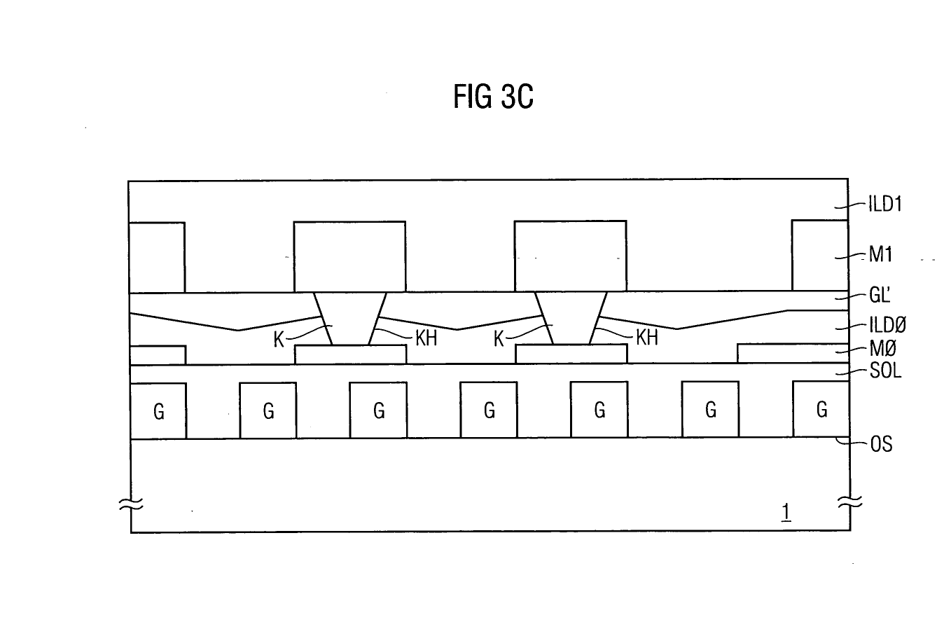

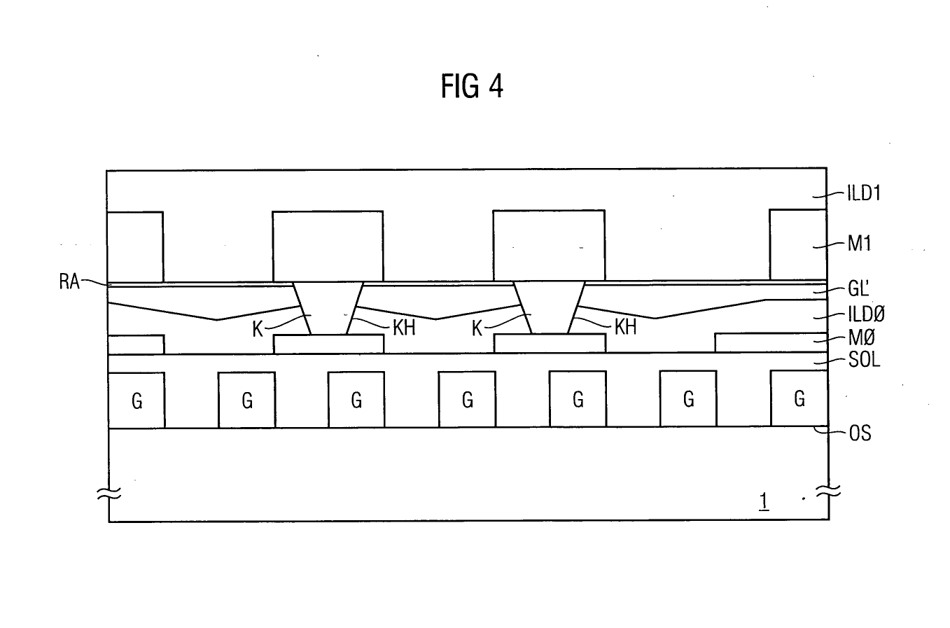

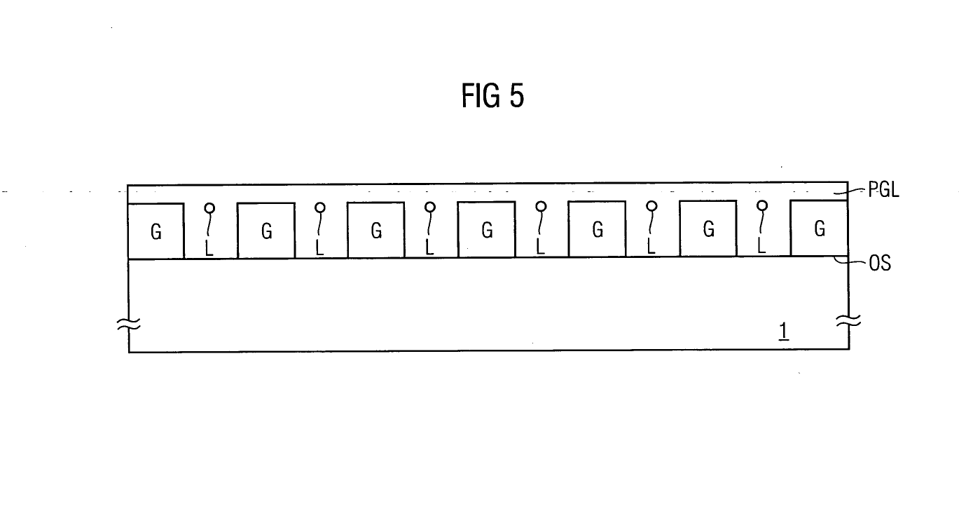

FIG. 4 shows a schematic layout for illustrating a manufacturing method for an integrated semiconductor structure according to a fourth embodiment of the present invention.

According to the fourth embodiment, the getter layer GL′ is deposited without any doping on the interlevel insulating layer ILD0, e.g. as pure silicate-glass. Thereafter and before formation of the contacts K an ion-implantation step for implanting phosphorous ions into the getter layer GL′ is performed. The parameters of this ion-implantation step are chosen such that a roughening of a surface area of the getter layer GL′ is effected which improves the adhesion to the second level wiring metal layer M1 and allows omission of the adhesion layer described in connection with the second embodiment shown in FIG. 2.

However, it is possible as well to additionally add said adhesion layer to the embodiment shown in FIG. 4 which further improves the adhesion of the second level wiring metal layer M1 and exhibits the aforementioned diffusion barrier function against foreign ions penetrating from above.

Although the present invention has been described with reference to a preferred embodiment, it is not limited thereto, but can be modified in various manners which are obvious for a person skilled in the art. Thus, it is intended that the present invention is only limited by the scope of the claims attached herewith.

Although not shown here, the lowest level metal wiring layer M0 and corresponding interlevel insulating layer ILD0 can be formed in damascene-level type, i.e. metal and interlevel dielectric extend to the same upper height.

Such a damascene technique would be performed by forming a insulating layer on said main surface, etching trenches in said insulating layer, depositing said wiring metal layer above said trenched insulating layer, and planarizing said wiring metal layer such that it only remains in said trenches.

Moreover, said metal layers can be any level metal layers.

Moreover, if necessary, the getter layer can be annealed immediately after its formation, especially if the getter layer is implanted with phosphorous ions after its deposition.

Moreover, said interlevel insulating layer ILD0 could comprise a HDP oxide layer and a TEOS layer deposited thereon. If the underlying structure is non-planar said TEOS layer could be planarized in a planarizing step before the getter layer is deposited thereon.

1. A manufacturing method for an integrated circuit having a semiconductor structure, comprising the steps of:
providing a substrate with a main surface;
forming a wiring metal layer above said main surface;
forming a doped getter layer over said wiring metal layer; and
forming at least one additional wiring metal layer over said doped getter layer.

2. The manufacturing method according to claim 1, wherein said doped getter layer is a PSG layer doped with 0.01%-10% by weight phosphorous.

3. The manufacturing method according to claim 1, further comprising the steps of:
forming a structure having a non-planar topology over said main surface; and
planarizing said structure with a planarization layer;
wherein said wiring metal layer is formed in or over said planarization layer.

4. The manufacturing method according to claim 3, wherein said structure having a non-planar topology comprises a plurality of gate stacks.

5. The manufacturing method according to claim 3, wherein said planarization layer is a spin-on glass.

6. The manufacturing method according to claim 3, wherein said planarization layer is undoped.

7. The manufacturing method according to claim 1, wherein said wiring metal layer is formed in a damascene technique by forming an insulating layer, etching trenches in said insulating layer, depositing said wiring metal layer above said trenched insulating layer, and planarizing said wiring metal layer such that it only remains in said trenches.

8. The manufacturing method according to claim 1, wherein said wiring metal layer is formed by forming an insulating layer depositing said wiring metal layer above said insulating layer, and patterning said wiring metal layer in a lithography/etching technique.

9. The manufacturing method according to claim 8, wherein said doped getter layer is deposited directly on said wiring metal layer.

10. The manufacturing method according to claim 8, wherein an interlevel insulating layer is deposited over said wiring metal layer and said doped getter layer is deposited over said interlevel insulating layer.

11. The manufacturing method according to claim 8, wherein an interlevel insulating layer is deposited over said wiring metal layer and said doped getter layer is deposited over said interlevel insulating layer, wherein after a planarizing step for planarizing said doped getter layer is performed.

12. The manufacturing method according to claim 8, wherein an interlevel insulating layer is deposited over said wiring metal layer, a planarizing step for planarizing said interlevel insulating layer is performed, wherein after said doped getter layer is deposited over said planarized interlevel insulating layer.

13. The manufacturing method according to claim 8, wherein said interlevel insulating layer is planarized.

14. The manufacturing method according to claim 12, wherein said interlevel insulating layer comprises a HDP oxide layer and a TEOS layer deposited thereon, and wherein said TEOS layer is planarized in said planarizing step.

15. The manufacturing method according to claim 1, wherein said wiring metal layer is a tungsten layer.

16. The manufacturing method according to claim 1, wherein said doped getter layer is a gas phase doped layer.

17. The manufacturing method according to claim 1, wherein said doped getter layer is separately doped in an implantation step.

18. The manufacturing method according to claim 17, wherein said implantation step is chosen such that it roughens the upper surface of said doped getter layer in order to improve the adhesion of the at least one additional wiring metal layer to said doped getter layer.

19. The manufacturing method according to claim 1, wherein an adhesion layer is formed over said doped getter layer in order to improve the adhesion of the at least one additional wiring metal layer to said doped getter layer.

20. The manufacturing method according to claim 19, wherein said adhesion layer is an undoped silane oxide layer.

21. The manufacturing method according to claim 1 wherein contacts extending through said doped getter layer are formed in order to electrically connect said wiring metal layer with said at least one additional wiring metal layer.

22. The manufacturing method according to claim 1 wherein said doped getter layer is subjected to an annealing step.

23. An integrated circuit having a structure comprising:
a substrate with a main surface;
a wiring metal layer formed above said main surface;
a doped getter layer formed over said wiring metal layer; and
at least one additional wiring metal layer formed over said doped getter layer.

24. The integrated circuit according to claim 23, wherein said doped getter layer is a PSG layer doped with 0.01%-10% by weight phosphorous.

25. The integrated circuit according to claim 23, wherein a structure having a non-polar topology is formed on said main surface; and said structure is planarized with a planarization layer; wherein said wiring metal layer is formed in or over said planarization layer.

26. The integrated circuit according to claim 25, wherein said structure having a non-polar topology comprises a plurality of gate stacks.

27. The integrated circuit according to claim 23, wherein said planarization layer is a spin-on glass layer.

28. The integrated circuit according to claim 23, wherein said planarization layer is undoped.

29. The integrated circuit according to claim 23, wherein said wiring metal layer is formed in a damascene technique by forming an insulating layer, etching trenches in said insulating layer, depositing said wiring metal layer above said trench insulating layer, and planarizing said wiring metal layer such that it only remains in said trenches.

30. The integrated circuit according to claim 23, wherein said wiring metal layer is formed by forming an insulating layer depositing said wiring metal layer above said insulating layer, and patterning said wiring metal layer in a lithography/etching technique.

31. The integrated circuit according to claim 23, wherein said doped getter layer is formed directly on said wiring metal layer.

32. The integrated circuit according to claim 23, wherein an interlevel insulating layer is formed over said wiring metal layer and said doped getter layer is formed over said interlevel insulating layer.

33. The integrated circuit according to claim 32, wherein said interlevel insulating layer comprises a HDP oxide layer and a TEOS layer formed thereover.

34. The integrated circuit according to claim 23, wherein said wiring metal layer is a tungsten layer.

35. The integrated circuit according to claim 23, wherein said doped getter layer is a gas phase doped layer.

36. The integrated circuit according to claim 23, wherein an adhesion layer is formed over said doped getter layer.

37. The integrated circuit according to claim 36, wherein said adhesion layer is an undoped silane oxide layer.

38. The integrated circuit according to claim 23, wherein contacts extending through said doped getter layer are formed in order to electrically connect said wiring metal layer with said at least one additional wiring metal layer.

39. An integrated circuit having a memory device, comprising:
a substrate having a main surface including a plurality of gate stacks;
a planarization layer formed over the plurality of gate stacks;
a wiring metal layer formed in or over said planarization layer;
an interlevel insulating layer formed over said wiring metal layer;
a doped getter layer formed over said interlevel insulating layer; and
at least one additional wiring metal layer formed on over said doped getter layer.

40. The manufacturing method of claim 3, further comprising performing a chemical mechanical polishing operation, thereby further planarizing said structure.
